(19) United States
(12) Patent Application Publication
(10) Pub. No.: US 2010/0020524 A1
(43) Pub. Date: Jan. 28, 2010

(54) PROTECTIVE PACKAGE FOR AN ELECTROMECHANICAL MICRO-SYSTEM COMPRISING A WIRING RELAY

(75) Inventors: Serge Parbaud, Saint Marcel Les Valence (FR); Regis Quer, Saint Peray (FR); Alain Fourrier, Valence (FR)

Correspondence Address: LOWE HAUPTMAN HAM & BERNER, LLP, 1700 DIAGONAL ROAD, SUITE 300, ALEXANDRIA, VA, 22314, US

(73) Assignee: THALES, NEUILLY SUR SENE (FR)

(21) Appl. No.: 12/518,703

(22) PCT Filed: Nov. 28, 2007
(86) PCT No.: PCT/EP07/62928

§ 371 Date: Jul. 29, 2009

(30) Foreign Application Priority Data
Dec. 12, 2006 (FR) 0610817

(51) Int. Cl. B81B 7/00

(52) U.S. Cl. 361/820

(57) ABSTRACT

The field of the invention is that of the wiring of electromechanical micro-systems also called MEMS (the acronym standing for Micro Electro Mechanical Systems) and more particularly micro-systems carrying out measurements of physical quantities such as for example micro-gyrometers, micro-accelerometers or pressure micro-sensors. More precisely the subject of the invention is a wiring relay for an electromechanical micro-system enclosed in a protective package. A first end of a wire bond of electrically conducting material is fixed to the micro-system electrical contact. The relay is fixed to at least one internal wall. The relay consists of an electrically insulating material. According to the invention, it comprises tracks of electrically conducting material, and one track is linked electrically with at least one internal electrical contact and with a second end of a wire bond.

### CROSS-REFERENCE TO RELATED APPLICATIONS

The present Application is based on International Application No. PCT/EP2007/062928, filed on Nov. 28, 2007, which in turn corresponds to French Application No. 0610817, filed on Dec. 12, 2006, and priority is hereby claimed under 35 USC §119 based on these applications. Each of these applications are hereby incorporated by reference in their entirety into the present application.

### FIELD OF THE INVENTION

The field of the invention is that of the wiring of electromechanical micro-systems also called MEMS (the acronym standing for Micro Electro Mechanical Systems) and more particularly micro-systems carrying out measurements of physical quantities such as for example micro-gyrometers, micro-accelerometers or pressure micro-sensors.

### BACKGROUND OF THE INVENTION

MEMS are systems which are very sensitive to thermal and mechanical stresses, and this is the reason why, in order to operate them, it is necessary to confine them in a leaktight protective package in which a controlled atmosphere prevails.

FIG. 1 represents such a protective package 10 in cross-sectional view. The package 10 comprises a base 12 and a cover 11 which are secured together by solder joints 15; the package 10 forms a sealed enclosure, in which a controlled atmosphere can be set up.

A MEMS electromechanical micro-system 1 generally has a substantially plane form comprising two faces: in fact a MEMS electromechanical micro-system 1 can be composed of a simple plane structure produced by machining a substrate of silicon on insulator (SOI) or of quartz or of another material, but other methods are also possible, this being the case for some micro-accelerometers, or else can be composed of a stack of several layers machined from silicon, this being the case for some micro-gyrometers.

The MEMS electromechanical micro-system 1 is enclosed in the package 10. A first face of the MEMS micro-system 1 rests on several pads 2. The pads 2 are themselves placed on an internal wall of the base 12 of the package 10. The pads 2 are solder joint fixings which insulate the MEMS micro-system 1 from the package 10. The pads 2 generally possess identical heights so as to minimize the mechanical and thermal stresses on the MEMS micro-system 1.

A second face of the MEMS micro-system comprises micro-system electrical contacts 5 which constitute electrical inputs and outputs making it possible respectively to address electrical control signals to the MEMS micro-system for operating it or to convey electrical signals produced by the micro-system 1 out of the micro-system.

In general, transfers of electrical signals to the MEMS micro-system 1 and transfers of electrical signals originating from the MEMS micro-system 1 are carried out by wire bonds 20 (commonly known as “bondings”) which link the micro-system electrical contacts 5 and internal electrical contacts 16, disposed on the internal walls of the package. The internal electrical contacts 16 are linked electrically, by way of internal bonds 18, to external electrical contacts 17 supported by external walls of the base 12 of the package 10.

The micro-system electrical contacts 5 occupy, on the second face of the MEMS micro-system, a position which results from a design phase of the MEMS micro-system 1. However, it is not always possible to manage to place all the micro-system electrical contacts 5 on a peripheral zone of the second face of the MEMS micro-system. It is for this reason that, in order to be able to electrically link micro-system electrical contacts 5 and internal electrical contacts 16, it is necessary for the wire bonds 20 to reach lengths possibly exceeding a few millimetres.

This gives rise to two drawbacks:

A first drawback is related to the length of the wire bonds 20 necessary to link the micro-system electrical contacts 5 to the internal electrical contacts 16, for example when the micro-system electrical contacts 5 are situated in a central zone of the second face of the micro-system 1.

The wire bonds 20 are often metal wires of constant diameter. When a wire bond 20 has a very large length compared with its diameter, typically, when the ratio of the length to the diameter of a wire bond 20 exceeds a value of 50, the wire bond 20 is very fragile: the wire bond 20 is liable to bend easily, notably when the package 10 is subjected to very large accelerations. The bending of the wire bonds 20 has the effect of considerably modifying the value of the capacitances appearing at the terminals of the micro-system electrical contacts. This constitutes a serious drawback since, in general, the micro-system 1 bases its measurements on detecting variations in capacitances between some of its contacts. Now, some micro-systems are intended to be borne onboard a carrier subjected to a large acceleration, for example an aircraft or a projectile, and the modifications of capacitances induced by the bending of the wire bonds 20 have a large amplitude compared with the variations in capacitances induced by the physical quantities to be measured.

A second drawback is also related to the relative positions occupied respectively by the micro-system electrical contacts 5 on the second face of the MEMS micro-system 1 and by the internal electrical contacts 16 on the internal walls of the package 10. In certain cases, these relative positions require that the wire bonds 20 overlap or cross. When the packages are subjected to very high accelerations, for example of the order of 20 000 g (where g is the terrestrial acceleration), the wire bonds 20 which cross may come into contact with one another: this may give rise to short-circuits.

### SUMMARY OF THE INVENTION

The aim of the invention is to alleviate these drawbacks. More precisely the subject of the invention is a protective package of an electromechanical micro-system integrated into the said package, consisting of walls of electrically insulating material, the said package forming a sealed enclosure, a wall possessing an internal face directed towards the interior of the enclosure and an external face in contact with the exterior of the enclosure, internal electrical contacts being disposed on the internal faces, external electrical contacts being disposed on the external faces, the internal electrical contacts and the external electrical contacts being linked electrically pairwise, the said micro-system being substantially plane, a first face of the micro-system being fixed to an internal wall of the package, a second face of the micro-system including micro-system electrical contacts, a first end of a wire bond of electrically conducting material being fixed to the micro-system electrical contact, characterized in that it includes a wiring relay fixed to at least one internal wall, the said relay consisting of an electrically insulating material and including tracks of electrically conducting material, one track being linked electrically with at least one internal electrical contact and with a second end of a wire bond, the said relay furthermore including at least one orifice through which the wire bond passes.

A first advantage of the invention is that it makes it possible to link micro-system electrical contacts 5 to internal electrical contacts 16 by employing wire bonds 20 which have a relatively short length and which, in fact, very rarely bend even when they are subjected to accelerations possibly exceeding 20 000 g.

A second advantage of the invention is related to a simplification of the design rules of the micro-system. Indeed, in the prior art, the position of the micro-system electrical contacts 5 on the second face of the micro-system is constrained by the position of the internal electrical contacts 16 on the internal walls of the package 10: thus, when designing a MEMS electromechanical micro-system 1, one seeks on the one hand to dispose the micro-system electrical contacts 5 on a peripheral zone of the second face of the micro-system and on the other hand to limit the overlaps, or crossovers, between wire bonds 20 when the design rules related to the fabrication of the micro-system so allow. By employing a wiring relay according to the invention, it is no longer necessary to confine the micro-system electrical contacts 5 on the periphery of the second face of the micro-system; it is also easier to avoid overlaps of wire bonds 20: design constraints of the electromechanical micro-system are thus considerably eased.

A third advantage of the invention is that the wiring relay according to the invention can, furthermore, include electronic components which can serve to implement the micro-system 1 or else possibly serve to process electrical signals produced by the micro-system 1.

Still other objects and advantages of the present invention will become readily apparent to those skilled in the art from the following detailed description, wherein the preferred embodiments of the invention are shown and described, simply by way of illustration of the best mode contemplated of carrying out the invention. As will be realized, the invention is capable of other and different embodiments, and its several details are capable of modifications in various obvious aspects, all without departing from the invention. Accordingly, the drawings and description thereof are to be regarded as illustrative in nature, and not as restrictive.

### BRIEF DESCRIPTION OF THE DRAWINGS

The present invention is illustrated by way of example, and not by limitation, in the figures of the accompanying drawings, wherein elements having the same reference numeral designations represent like elements throughout and wherein:

FIG. 1, already described, represents a protective package enclosing an electromechanical micro-system, in sectional view;

FIG. 2 represents a protective package according to the invention protecting an electromechanical micro-system and comprising a wiring relay according to the invention;

FIG. 3 represents, in perspective view, a first embodiment of a wiring relay according to the invention along a first face and a second face;

FIG. 4 represents, in perspective view, a second embodiment of a wiring relay according to the invention along a first face and a second face.

### DETAILED DESCRIPTION OF THE INVENTION

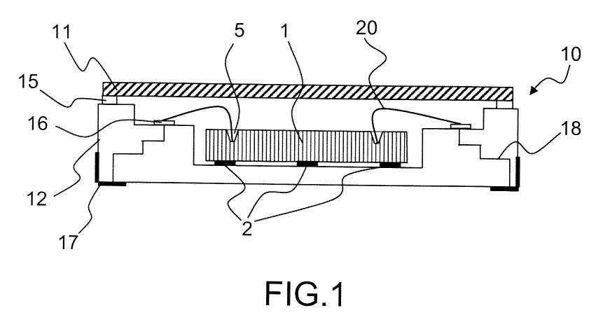

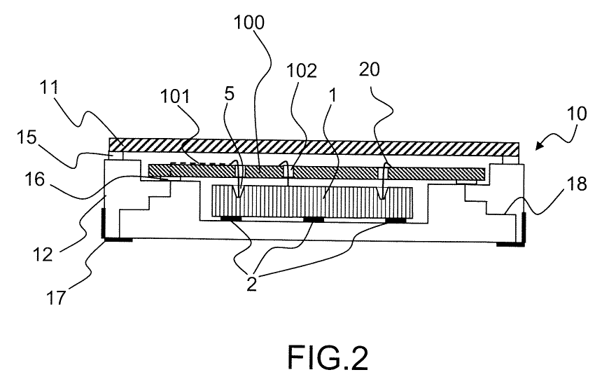

FIG. 2 represents a package protecting an electromechanical micro-system 1. This package is distinguished from the package presented in FIG. 1 in that it comprises, furthermore, a wiring relay according to the invention 100.

Advantageously, the wiring relay according to the invention is substantially plane.

The wiring relay is in general composed of a plate 100 consisting of an electrically insulating material. The plate 100 is in general fixed to at least one internal wall of the package 10. The plate comprises a first face and a second face. Tracks 101 represented by dashes in the figure, run along the first and the second faces of the plate.

The tracks 101 consist of an electrically conducting material: for example, the plate 100 is made of epoxy resin and the tracks 101 are made of copper. The plate 100 can comprise tracks 101 which run on several levels: in this case one speaks of “multilayer” tracks 101.

The tracks 101 in general comprise two ends:

a first end 105 which is linked electrically to the internal electrical contacts 16 which are disposed on the internal walls of the base 12 of the package 10,

a second end which is bonded to one of the second ends of a wire bond 20.

The wire bonds 20 comprise a first end fixed to a micro-system electrical contact 5 and a second end linked electrically to a second end of the tracks 101.

Advantageously, a wire bond is a metal wire of constant diameter and the wire has a length which is less than fifty times the diameter of the wire.

Advantageously, the wire bonds have a diameter equal to 25 micrometres.

On account of the existence of tracks 101 on the wiring relay according to the invention, the wire bonds 5 used in a protective package of an electromechanical micro-system comprising such a relay have a shorter length than that of the wire bonds 5 employed in a protective package devoid of wiring relay.

The short length of the wire bonds is why the resistance to bending of the wire bonds is high, even when they are subjected to accelerations of as much as 20 000 g.

Advantageously, the wiring relay according to the invention is disposed in a manner substantially parallel to the second face of the micro-system component and a first face of the relay faces the second face of the component.

Advantageously, the wiring relay according to the invention comprises orifices through which the wire bonds pass.

To mount the electromechanical micro-system 1 in the package, the micro-system is first of all fixed to a wall of the base 12 of the package 10. Subsequently, the wiring relay according to the invention is fixed to the base 12 of the package 10 in such a way that the first ends of the tracks 101 are electrically linked to the internal electrical contacts 16.

The first ends of the wire bonds 20 are thereafter fixed to the micro-system electrical contacts 5. The fixing is carried out by placing a first end of the wire bonds 20 on the micro-system electrical contacts 5 by virtue of so-called “well-base” bonding tools. Placement is effected by introducing the tools and the wire bonds 20 into orifices 102 disposed above the micro-system electrical contacts 5, vertically in line with and in direct proximity to these contacts 5.

Next, the second end of the wire bonds is secured to the second end of a track 101 placed at least partially on a second face of the relay.

Finally the cover, 11 is fixed to the base of the package 10, in general by means of solder joints.

It is possible to establish a controlled atmosphere in the enclosure formed by the cover 11 and by the base 12.

Advantageously, the enclosure is hermetically sealed and a vacuum of less than 10⁻⁴ millibars prevails in the enclosure.

Advantageously, the tracks are linked to the second ends of the wire bonds on a second face of the said relay.

Advantageously, a ratio between an area of an orifice and a cross section of a wire bond which passes through it is greater than 1600.

The orifices 102 have a sufficient area so that the “well-base” bonding tools introduced through these orifices 102 can reach the micro-system electrical contacts 5.

It is also indispensable that an orifice 102 have a sufficient area so that a wire bond 20 passing through it does not come into contact with the wiring relay. For example, the orifice 102 has a circular form and possesses a diameter equal to 1000 micrometres and the wire bond 20 is a metal wire with a right cross section which possesses a diameter equal to 25 micrometres.

Advantageously, the wiring relay according to the invention comprises, furthermore, electronic components which are linked to tracks.

Two categories of micro-systems 1 are usually considered:

a first category of micro-systems that may be described as permeable. These micro-systems have walls which cannot maintain an atmosphere under vacuum inside the micro-system;

a second category of micro-systems that may be described as hermetic. These micro-systems have walls which can preserve an atmosphere under vacuum.

Micro-systems 1 belonging to the first category must necessarily be protected by packages which are themselves hermetic, that is to say they are packages inside which it is possible to maintain an atmosphere under vacuum. The operation of such micro-systems 1 is adversely affected by a presence of electronic components disposed on one or more faces of the wiring relay for providing electrical signals serving in the operation of the micro-system or for processing electrical signals produced by the micro-system. Indeed, these components produce degassings which impair the vacuum drawn in the enclosure.

Micro-systems belonging to the second category can be enclosed in protective packages 10 which are not necessarily totally leaktight, that is to say they are packages inside which a neutral atmosphere prevails. Operation of the micro-system is not adversely affected by possible degassings of electronic components disposed on one of the faces of the relay.

Advantageously, the electronic components produce electrical signals employed to operate the micro-system.

Advantageously, the electronic components gather electrical signals produced by the micro-system.

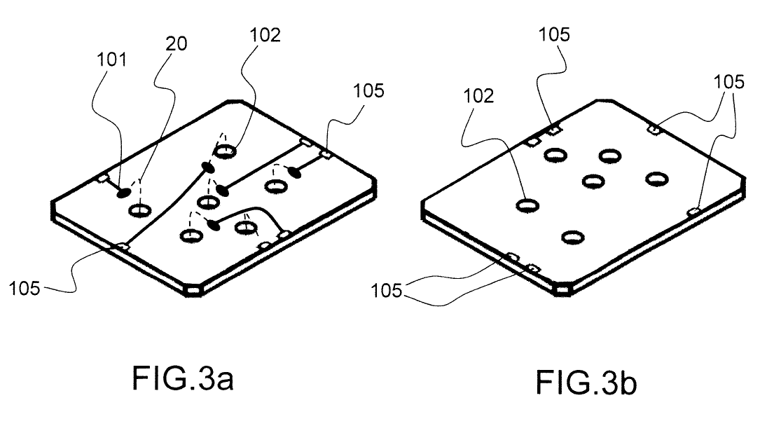

FIGS. 3a and 3b represent in perspective view a first embodiment of a wiring relay according to the invention. FIG. 3a represents the second face of the first embodiment. FIG. 3b represents the first face of the first embodiment.

This embodiment is preferably adapted to a micro-system 1 comprising a not very large number of micro-system electrical contacts 5, for example when the number of micro-system electrical contacts 5 to be linked to external contacts 17 is less than or equal to 6.

For this embodiment, which corresponds to the sectional view represented in FIG. 2, a second end of the tracks 101, represented by a black disc, is placed on the second face of the relay, in proximity to an orifice 102 in the plate of the relay.

A wire bond 20 represented by dashes possesses a first end 105 secured to a micro-system electrical contact 5—the first end is not represented in FIG. 3a—and a second end which is linked to the second end of the tracks 101.

The tracks 101 link their second end to a first end 105, which is represented by a white rectangle in FIG. 3a. The first ends 105 are placed in proximity to a peripheral zone of the plate and are emergent, that is to say they also appear on a first face of the relay of the plate 100 of the relay.

In FIG. 3b are observed the first ends 105 of the tracks 101 which occupy on the plate 100 a position which places it in contact with internal electrical contacts 16 of the package 10.

A first step of assembling the first embodiment of the relay according to the invention to the base 12 of the package 10 consists in soldering the internal electrical contacts 16, not visible in FIGS. 3a and 3b, with the second ends 105 of the tracks 101 so as on the one hand to fix the relay to the package and on the other hand to electrically link the external electrical contacts 17 and the second ends of the tracks 101.

A second step of assembling the relay to the base of the package 10 consists in fixing the two ends of the wire bonds 20, as was presented above, respectively to the micro-system electrical contacts and to the second ends of the tracks 101.

The form of the plate 100 is shaped so as to permit introduction into the package of the relay according to the invention.

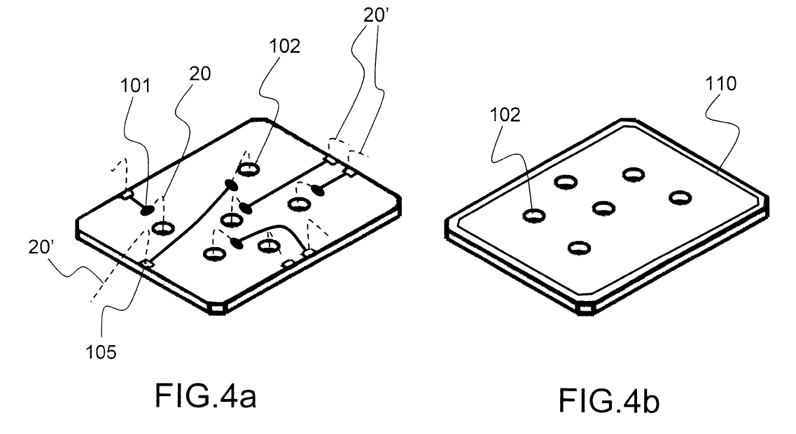

FIGS. 4a and 4b represent in perspective view a second embodiment of a wiring relay according to the invention. FIG. 4a represents the second face of the second embodiment. FIG. 4b represents the first face of the second embodiment.

This embodiment is preferably adapted to a micro-system 1 comprising a large number of micro-system electrical contacts 5, for example when the number of micro-system contacts to be linked to external contacts is greater than or equal to 6.

The second face of the second embodiment of the relay is distinguished from the second face of the first embodiment, in that the tracks 101 are extended by ancillary wire bonds 20′ and in that the first ends 105 of the tracks 101 are not emergent.

One end of the ancillary wire bonds 20′ is bonded to the first end 105 of the track 101, which is represented by a white rectangle in FIG. 4a. The first end 105 is placed in proximity to the edges of the plate 100.

The first face of the second embodiment of the relay differs from the first face of the first embodiment of the relay in that it comprises a soldering zone 110 covering edges of the plate 100.

A first step of assembling the second embodiment of the relay according to the invention to the base of the package consists in securing the plate and the base 12 of the package 10 by depositing soldering material on the soldering zone 110.

A second step of assembling the relay consists in fixing two ends of the wire bonds 20 as was presented above respectively to the micro-system electrical contacts 5 and to the second ends of the tracks 101.

A third step of assembling consists in fixing two ends of the auxiliary wire bonds 20′ respectively to the internal contacts 16 and to the first ends 105 of the track 101.

When a micro-system comprises a large number of micro-system electrical contacts 5 and the second ends 105 of the track 101 are numerous and very close together, it is easier to assemble this second embodiment of the relay to a base 12 of the package 10 than the first embodiment. This is due to the fact that the assembling of the first embodiment of the relay according to the invention to the base 12 of a package 10 is very tricky to carry out because of the difficulty of depositing soldering material on second ends 105 which are very close together, for example when these second ends 105 are separated by a few tens of micrometres.

It will be readily seen by one of ordinary skill in the art that the present invention fulfils all of the objects set forth above. After reading the foregoing specification, one of ordinary skill in the art will be able to affect various changes, substitutions of equivalents and various aspects of the invention as broadly disclosed herein. It is therefore intended that the protection granted hereon be limited only by definition contained in the appended claims and equivalents thereof.

1. A protective package of an electromechanical micro-system integrated into the package, having walls of electrically insulating material, the package forming a sealed enclosure, a wall possessing an internal face directed towards the interior of the enclosure and an external face in contact with the exterior of the enclosure, internal electrical contacts being disposed on the internal faces, external electrical contacts being disposed on the external faces, the internal electrical contacts and the external electrical contacts being linked electrically pairwise, said micro-system being substantially plane, a first face of the micro-system being fixed to an internal wall of the package, a second face of the micro-system comprising micro-system electrical contacts, a first end of a wire bond of electrically conducting material being fixed to the micro-system electrical contact, said protective package comprising a wiring relay fixed to at least one internal wall, said relay having an electrically insulating material and comprising tracks of electrically conducting material, one track being linked electrically with at least one internal electrical contact and with a second end of a wire bond, said relay furthermore comprising at least one orifice through which the wire bond passes.

2. The protective package of an electromechanical micro-system according to claim 1, wherein the wiring relay is disposed in a manner substantially parallel to the second face of the micro-system and in that a first face of the relay faces the second face of the micro-system.

3. The protective package of an electromechanical micro-system according to one claim 1, wherein the tracks are linked to the second ends of the wire bonds on a second face of the said relay.

4. The protective package of an electromechanical micro-system according to claim 1, wherein a ratio between an orifice area and a cross section of a wire bond which passes through the orifice is greater than 1600.

5. The protective package of an electromechanical micro-system according to claim 1, wherein the wiring relay comprises, furthermore, electronic components which are linked electrically to tracks.

6. The protective package of an electromechanical micro-system according to claim 5, wherein the electronic components produce electrical signals employed to operate the micro-system.

7. The protective package of an electromechanical micro-system according to claim 6, wherein the electronic components gather electrical signals produced by the micro-system.

8. The protective package according to claim 1, wherein a wire bond is a metal wire of constant diameter and in that the wire has a length which is less than fifty times the diameter of the wire.

9. The protective package according to claim 1, wherein the enclosure is hermetically sealed and in that a vacuum of less than 10⁻⁴ millibars prevails in the enclosure.

10. The protective package according to claim 1, wherein the wire bonds have a diameter equal to 25 micrometres.

11. A protective package of an electromechanical micro-system integrated into the package, having walls of electrically insulating material, the package forming a sealed enclosure, a wall possessing an internal face directed towards the interior of the enclosure and an external face in contact with the exterior of the enclosure, internal electrical contacts being disposed on the internal faces, external electrical contacts being disposed on the external faces, the internal electrical contacts and the external electrical contacts being linked electrically pairwise, said micro-system being substantially plane, a first face of the micro-system being fixed to an internal wall of the package, a second face of the micro-system comprising micro-system electrical contacts, a first end of a wire bond of electrically conducting material being fixed to the micro-system electrical contact, said protective package comprising a wiring relay fixed to at least one internal wall, said relay having an electrically insulating material and comprising tracks of electrically conducting material, one track being linked electrically with at least one internal electrical contact and with a second end of a wire bond, said relay furthermore comprising at least one orifice through which the wire bond passes.

12. The protective package of an electromechanical micro-system according to claim 11, wherein the wiring relay is disposed in a manner substantially parallel to the second face of the micro-system and in that a first face of the relay faces the second face of the micro-system.

13. The protective package of an electromechanical micro-system according to claim 11, wherein the tracks are linked to the second ends of the wire bonds on a second face of the said relay.

14. The protective package of an electromechanical micro-system according to claim 11, wherein a ratio between an orifice area and a cross section of a wire bond which passes through the orifice is greater than 1600.

15. The protective package of an electromechanical micro-system according to claim 11, wherein the wiring relay comprises, furthermore, electronic components which are linked electrically to tracks.

16. The protective package of an electromechanical micro-system according to claim 15, wherein the electronic components produce electrical signals employed to operate the micro-system.

17. The protective package of an electromechanical micro-system according to claim 16, wherein the electronic components gather electrical signals produced by the micro-system.

18. The protective package according to claim 11, wherein a wire bond is a metal wire of constant diameter and in that the wire has a length which is less than fifty times the diameter of the wire.

19. The protective package according to claim 11, wherein the enclosure is hermetically sealed and in that a vacuum of less than 10⁻⁴ millibars prevails in the enclosure.

20. The protective package according to claim 11, wherein the wire bonds have a diameter equal to 25 micrometres.
